(19) United States
(12) Patent Application Publication
(10) Pub. No.: US 2025/0113615 A1
(43) Pub. Date: Apr. 3, 2025

(54) ARRAY SUBSTRATE AND DISPLAY PANEL

(71) Applicant: Wuhan China Star Optoelectronics Technology Co., Ltd., Wuhan, Hubei (CN)

(72) Inventor: Chengzhi LUO, Wuhan, Hubei (CN)

(73) Assignee: Wuhan China Star Optoelectronics Technology Co., Ltd., Wuhan, Hubei (CN)

(21) Appl. No.: 18/289,038

(22) PCT Filed: Sep. 21, 2023
(86) PCT No.: PCT/CN2023/120329

§ 371 Date: Oct. 31, 2023

(30) Foreign Application Priority Data
Sep. 15, 2023 (CN) 202311199964.9

(51) Int. Cl. H10D 86/60; H10D 86/40

(52) U.S. Cl. CPC H10D 86/60; H10D 86/421

(57) ABSTRACT

An embodiment of the present disclosure discloses an array substrate and a display panel; The array substrate has a display region and includes a substrate, and a thin film transistor layer on a side of the substrate. The thin film transistor layer includes a plurality of first thin film transistors arranged in a first direction, the first thin film transistors are located in the display region, the second gates of adjacent first thin film transistors are connected in the first direction, and the first gates of at least two first thin film transistors are arranged at intervals.

### TECHNICAL FIELD

The present disclosure relates to a display field, and more particularly, to an array substrate and a display panel.

### BACKGROUND

With the development of display technology, a mobile phone, a television, a personal digital assistant, a digital camera, a notebook computer, a desktop computer, a virtual reality (VR), an augmented reality (AR), and the like come into being depending on the consumer electronic product application of a display device. Display devices such as the display devices in VR, AR, or the like, which have a higher demand for resolution, increase the pixel density of the display panel in order to provide high resolution, thereby making it difficult to improve an aperture ratio.

Accordingly, there is a need for an array substrate and a display panel to solve the above technical problems.

### SUMMARY

The present disclosure provides a display panel and a manufacturing method thereof, which may alleviate the technical problem that the aperture ratio of a display device having a high resolution requirement is difficult to be increased.

### TECHNICAL SOLUTION

To solve the above problems, the present disclosure provides the following technical solutions:

The present disclosure provides an array substrate having a display region, the array substrate including:

a substrate; and

a thin film transistor layer on a side of the substrate, wherein the thin film transistor layer includes a plurality of first thin film transistors arranged in a first direction, and the first thin film transistors are located in a display region;

wherein each of the first thin film transistors includes a first gate and a second gate, and the second gate is located on a side of the first gate away from the substrate,

the second gates of adjacent ones of the first thin film transistors are connected in the first direction, and the first gates of at least two of the first thin film transistors are spaced apart in the first direction.

Alternatively, the first gates of adjacent ones of the first thin film transistors are spaced apart in the first direction.

Alternatively, an orthographic projection of the second gate on the substrate overlaps an orthographic projection of the first gate on the substrate.

Alternatively, in the first direction, an interval between the first gates of adjacent ones of the first thin film transistors is greater than or equal to 1 micron, and the interval between the first gates of adjacent ones of the first thin film transistors is less than or equal to 6.6 microns.

Alternatively, the thin film transistor layer further includes a first via hole located between the first gate and the second gate, and the first gate and the second gate of each of the first thin film transistors are connected in the first via hole in the first direction.

Alternatively, the first thin film transistor further includes a first active layer between the first gate and the second gate, and the first via hole is located on a side of the first active layer in the first direction.

Alternatively, in the first direction, the first gate includes a first side and a second side opposite to each other, the first active layer is located between the first side and the second side, and the first via hole is located between the first side and the first active layer;

wherein, in the first direction, an interval between the first side and the orthographic projection of the first active layer on the first gate is greater than an interval between the second side and the first active layer.

Alternatively, n the first direction, the interval between the first side and the orthographic projection of the first active layer on the first gate is greater than or equal to 1.5 μm, and the interval between the first side and the orthographic projection of the first active layer on the first gate is less than or equal to 4 μm,

an interval between the second side and the orthographic projection of the first active layer on the first gate is greater than or equal to 0.5 μm, and the interval between the second side and the orthographic projection of the first active layer on the first gate is less than or equal to 2 μm.

Alternatively, the first thin film transistor further includes a first source and a first drain located on opposite sides of the first active layer in a second direction, the second direction intersects the first direction;

the first source and the first drain are located on a side of the first active layer away from the substrate, and the first source and the first drain are respectively connected to the first active layer;

the array substrate further includes a pixel electrode layer on a side of the thin film transistor layer away from the substrate, the pixel electrode layer includes a pixel electrode, and one of the first source and the first drain is connected to the pixel electrode.

Alternatively, the first source is connected to the pixel electrode, and a material of the first source is selected from a transparent conductive material.

Alternatively, the first drain is connected to the pixel electrode, and a material of the first drain is selected from a transparent conductive material.

Alternatively, the thin film transistor layer further includes a plurality of the first thin film transistors arranged in a second direction, the first gates of adjacent ones of the first thin film transistors are spaced apart in the second direction, and the second gates of adjacent ones of the first thin film transistors are spaced apart in the second direction;

wherein an interval between the first gates of the first thin film transistors adjacent in the second direction is greater than an interval between the first gates of the first thin film transistors adjacent in the first direction.

Alternatively, in the first direction, a connection portion is provided between the first gates of at least two of the first thin film transistors in the first direction, and the connection portion connects the first gates of the at least two of the first thin film transistors;

wherein an orthographic projection of the connection portion on the substrate is located within an orthographic projection of the second gate on the substrate.

Alternatively, the thin film transistor layer includes at least one first thin film transistor group in the first direction, and each of the at least one first thin film transistor group includes at least two of the first thin film transistors;

wherein in the first direction, the first gates of adjacent ones of the first thin film transistors in each of the at least one first thin film transistor group are connected, and the first gates of the first thin film transistors in the adjacent ones of the at least one first thin film transistor group are spaced apart.

Alternatively, each of the at least one first thin film transistor group is provided with a first via hole.

Alternatively, the array substrate further including a non-display region located on at least one side of the display region, the thin film transistor layer further including second thin film transistors located within the non-display region;

wherein the second thin film transistor includes a second source and a second drain, and one of the second source and the second drain of at least one of the second thin film transistors is connected to the second gate electrode of at least one of the first thin film transistors.

The present disclosure further provides a display panel including an array substrate including:

a substrate;

a thin film transistor layer on one side of the substrate, wherein the thin film transistor layer includes a plurality of first thin film transistors arranged in a first direction, and the first thin film transistors are located in a display region;

wherein each of the first thin film transistors includes a first gate and a second gate, and the second gate is located on a side of the first gate away from the substrate;

the second gates of adjacent ones of the first thin film transistors are connected in the first direction, and the first gates of at least two of the first thin film transistors are spaced apart in the first direction.

Alternatively, the first gates of adjacent ones of the first thin film transistors are spaced apart in the first direction.

Alternatively, an orthographic projection of the second gate on the substrate overlaps an orthographic projection of the first gate on the substrate.

Alternatively, in the first direction, a connection portion is provided between the first gates of the at least two of the first thin film transistors and the connection portion connects the first gates of the at least two of the first thin film transistors;

wherein an orthographic projection of the connection portion on the substrate is located within an orthographic projection of the second gate on the substrate.

### BENEFICIAL EFFECT

By arranging at least two first gates in a first direction at intervals, the present disclosure reduces the shielding of light by the first gates, thereby increasing the aperture ratio of a display panel to which an array substrate is applied.

### BRIEF DESCRIPTION OF THE DRAWINGS

FIG. 1 is a schematic block diagram of a configuration of an array substrate according to an embodiment of the present disclosure;

FIG. 2 is a schematic block diagram of a configuration of an array substrate according to another embodiment of the present disclosure;

FIG. 3 is a schematic diagram of a film layer structure of a first thin film transistor of an array substrate according to an embodiment of the present disclosure;

FIG. 4 is a schematic diagram of a film layer structure of a first thin film transistor of an array substrate according to another embodiment of the present disclosure;

FIG. 5 is a schematic diagram of a film structure of a first flat layer of an array substrate according to an embodiment of the present disclosure;

FIG. 6 is a schematic block diagram of a display panel according to an embodiment of the present disclosure.

### DETAILED DESCRIPTION

The present disclosure provides an array substrate and a display panel. In order to make the objective, technical solution and effect of the present disclosure clearer and more clarity, the present disclosure will be described in further detail below with reference to the accompanying drawings and embodiments. It is to be understood that the specific embodiments described herein are merely illustrative of the present disclosure and are not intended to limit the present disclosure.

At present, since the pixel density of the display panel is improved in order to achieve the high resolution, it is difficult to improve the aperture ratio of the display panel.

Referring to FIGS. 1 to 5, an embodiment of the present disclosure provides an array substrate 100 having a display region AA, the array substrate 100 including:

a substrate 101; and

a thin film transistor layer 102 on a side of the substrate 101, the thin film transistor layer 102 including a plurality of first thin film transistors 103 arranged in a first direction X, the first thin film transistors 103 being located in the display region AA;

The first thin film transistor 103 includes a first gate 104 and a second gate 105 located on a side of the first gate 104 away from the substrate 101.

In the first direction X, the second gates 105 of adjacent ones of the first thin film transistors 103 are connected, and the first gates 104 of at least two of the first thin film transistors 103 are spaced apart.

By arranging at least two first gates 104 at intervals in the first direction X, the embodiment of the present disclosure reduces the shielding of light by the first gates 104, thereby increasing the aperture ratio of the display panel to which the array substrate 100 is applied.

The technical solution of the present disclosure will now be described with reference to embodiments.

Referring to FIGS. 1 to 5, in this embodiment, in the thin film transistor layer 102, the plurality of first thin film transistors 103 are arranged in a second direction Y. The first gates 104 of adjacent ones of the first thin film transistors 103 are spaced apart in the second direction Y. The second gates 105 of adjacent ones of the first thin film transistors 103 are spaced apart in the second direction Y, and the second direction Y intersects the first direction X.

In some embodiments, the first thin film transistor 103 further includes a first active layer 106 located between the first gate 104 and the second gate 105. The first thin film transistor 103 further includes a first source 107 and a first drain 108 located on opposite sides of the first active layer 106 in a second direction Y. The first source 107 and the first drain 108 are located on a side of the first active layer 106 away from the substrate 101. The first source 107 and the first drain 108 are separately connected to the first active layer 106.

In some embodiments, in the second direction Y, the first sources 107 of first thin film transistors 103 adjacent with each other are connected, or, the first drains 108 of the first thin film transistors 103 adjacent with each other are connected.

In some embodiments, the first direction X is a row direction along which the second gates 105 of adjacent first thin film transistors 103 are connected, i.e., the second gates 105 of the first thin film transistors 103 in the same row are connected. The second gates 105 of the first thin film transistors 103 in the same row may be integrally provided to simplify the manufacturing process of the array substrate 100.

In some embodiments, the second direction Y is a column direction along which the first sources 107 or the first drains 108 of the adjacent first thin film transistors 103 are connected, i.e., the first sources 107 or the first drains 108 of the first thin film transistors 103 in the same column are connected. The first sources 107 or the first drains 108 of the first thin film transistor 103 in the same column may be integrally arranged to facilitate simplification of the manufacturing process of the array substrate 100.

In some embodiments, along the first direction X, the first gates 104 of adjacent first thin film transistors 103 are spaced apart, i.e., the first gates 104 of the first thin film transistors 103 located in the same row are spaced apart from each other by an interval greater than zero.

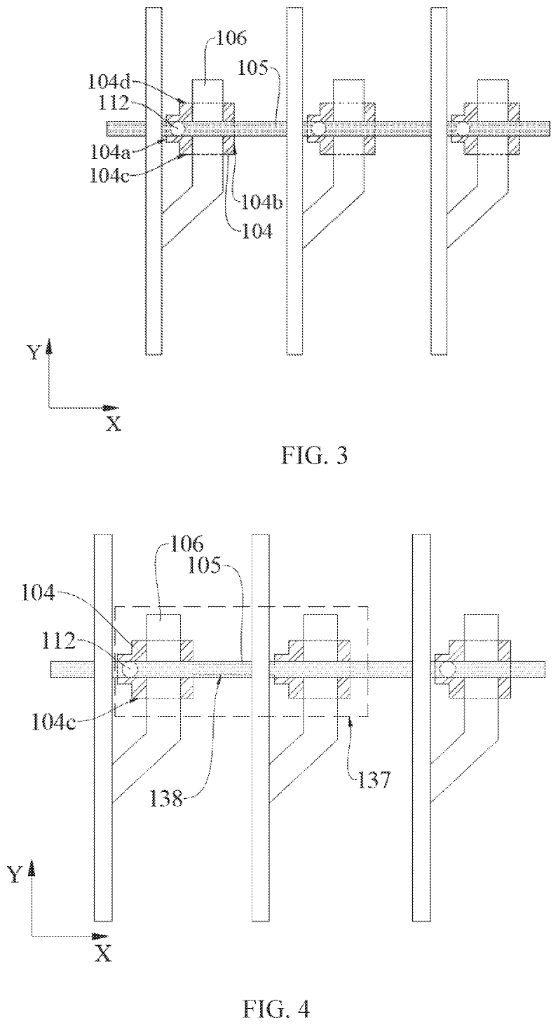

Referring to FIG. 3, in some embodiments, the orthographic projection of the second gate 105 on the substrate 101 overlaps the orthographic projection of the first gate 104 on the substrate 101.

In some embodiments, when the first gates 104 of adjacent ones of the first thin film transistors 103 along the first direction X are spaced apart, the interval between the first gates 104 of adjacent ones of the first thin film transistors 103 is greater than or equal to 1 micron, the interval between the first gates 104 of adjacent ones of the first thin film transistors 103 is less than or equal to 6.6 microns, to enhance the aperture ratio of the display panel to which the array substrate 100 is applied. For example, the interval may be 1.5 microns, 2 microns, 2.5 microns, 3 microns, 3.5 microns, 4 microns, 4.5 microns, 5 microns, 5.5 microns, 6 microns, 6.5 microns, etc. The intervals between the first gates 104 of the first thin film transistors 103 adjacent to each other in the first direction X are different at pixel densities corresponding to different resolutions, and the interval between the first gates 104 of the first thin film transistors 103 adjacent to each other in the first direction X is adjusted adaptively within the above range (for example, the interval between the first gates 104 of the first thin film transistor groups 103 adjacent to each other in the first direction X, when the pixel density is greater), so that the aperture ratio of the display panel to which the array substrate 100 is applied may be effectively improved.

In some embodiments, the interval between the first gates 104 of the adjacent first thin film transistors 103 in the second direction Y is greater than the interval between the first gates 104 of the adjacent first thin film transistors 103 in the first direction X. By interval the first gates 104 of the adjacent first thin film transistors 103 in the first direction X and the second direction Y, it is advantageous to substantially reduce the shielding of light by the first gates 104, to increase the aperture ratio of the display panel to which the array substrate 100 is applied, and to reduce power consumption while maintaining high resolution of the display panel to which the array substrate 100 is applied. Specifically, by interval the first gates 104 of adjacent first thin film transistors 103 in the first direction X and the second direction Y, the aperture ratio of a display panel having an original aperture ratio of 25% may be increased to 40%, which is experimentally verificated.

In some embodiments, in the second direction Y, the interval between the first gates 104 of adjacent first thin film transistors 103 is greater than or equal to 12.7 microns, and the interval between the first gates 104 of adjacent first thin film transistors 103 is less than or equal to 20.7 microns. For example, the interval between the first gates 104 of adjacent first thin film transistors 103 may be 13.7 microns, 14.7 microns, 15.7 microns, 16.7 microns, 17.7 microns, 18.7 microns, 19.7 microns, etc.

Referring to FIG. 1, in some embodiments, the first active layer 106 includes a first channel portion 109 and a first source contact portion 110 and a first drain contact portion 111 located on both sides of the first channel portion 109, respectively, in the second direction Y. The first source 107 is connected to the first source contact portion 110, and the first drain 108 is connected to the first drain contact portion 111. The first gate electrode 104 may be used to block light from a side of the substrate 101, and an orthographic projection of the first channel portion 109 on the first gate electrode 104 is located in the first gate electrode 104.

Referring to FIG. 3, in some embodiments, the first gate 104 includes first and second sides 104a and 104b at opposite sides of the first gate 104 in the first direction X. The first active layer 106 is located between the first and second sides 104a and 104b. The first active layer 106 is spaced apart from the first side 104a by an interval greater than zero, and the first active layer 106 is spaced apart from the second side 104b by an interval greater than zero, so that the first gate 104 completely blocks light from the side of the substrate 101 from irradiating on the first channel portion 109.

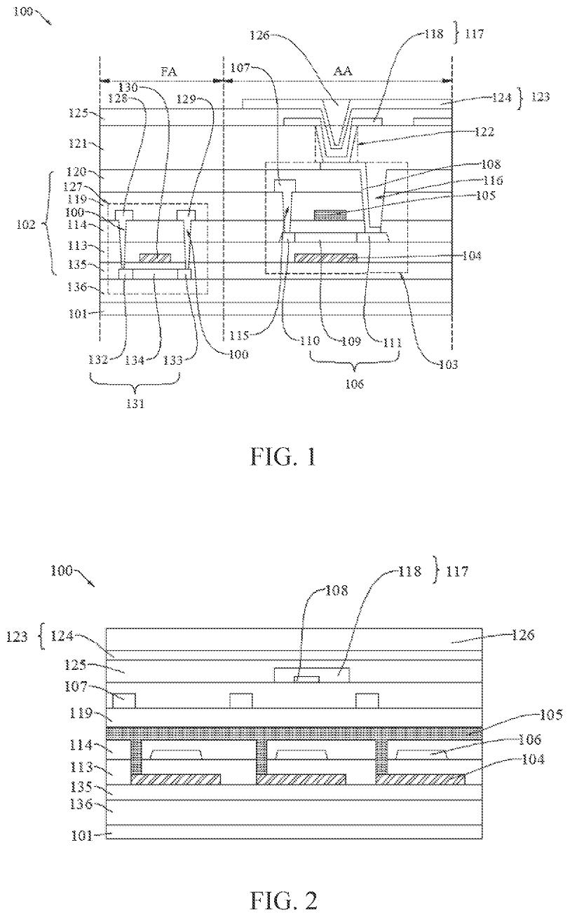

Referring to FIGS. 2 and 3, in some embodiments, the thin film transistor layer 102 further includes a first via hole 112 located between the first gate 104 and the second gate 105. When the first gates 104 of at least two of the first thin film transistors 103 in the first direction X are arranged at intervals, at least two of the first via holes 112 are respectively located between the first gates 104 arranged at intervals and the second gates 105, so that the first gates 104 and the second gates 105 of the first thin film transistors 103 in the same row are maintained at the same potential.

When the first gates 104 of adjacent ones of the first thin film transistors 103 in the first direction X are spaced apart, the first gate 104 of each of the adjacent first thin film transistors 103 in the first direction X and the second gate 105 of this first thin film transistor 103 are connected in the first via hole 112, so that the first gates 104 and the second gates 105 of the first thin film transistors 103 in the same row are kept at the same potential as each other.

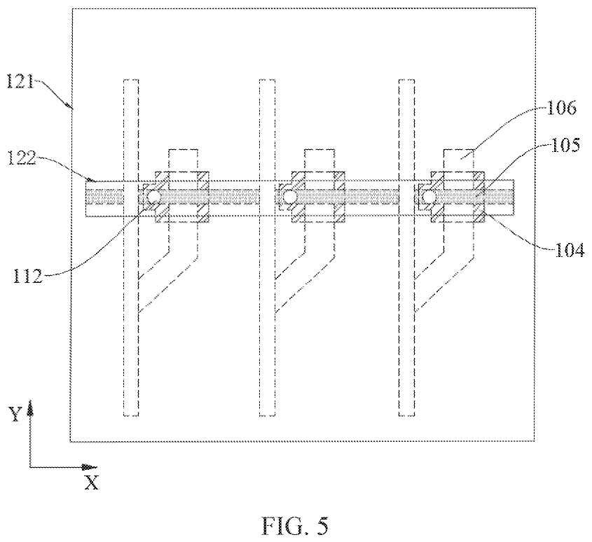

Referring to FIG. 4, in some embodiments, a connection 138 is provided between the first gates 104 of at least two of the first thin film transistors 103 in the first direction X, and the connection 138 connects the first gates 104 of the two first thin film transistors 103. The orthographic projection of the connection portion 138 on the substrate 101 is located in the orthographic projection of the second gate electrode 105 on the substrate 101, so as to reduce shielding of light by the connection portion 138, thereby facilitating increasing the aperture ratio of the display panel to which the array substrate 100 is applied. When the orthographic projection of the connection portion 138 on the substrate 101 is located in the orthographic projection of the second gate electrode 105 on the substrate 101, the width of the connection portion 138 in the second direction Y is smaller than or equal to the width of the second gate electrode 105 in the second direction Y.

By the arrangement of the connection portion 138, the first gates 104 of the at least two first thin film transistors 103 in the first direction X are connected, so that the number of the first via holes 112 is reduced, the resistance generated by the connection of the second gates 105 and the first gates 104 is reduced, the amount of power required to maintain first gates 104 of the first thin film transistors 103 in the same row have the same potential as the second gates 105 of these first thin film transistors 103 is reduced, and the power consumption of the display panel to which the array substrate 100 is applied is reduced.

Referring to FIG. 4, in some embodiments, along the first direction X, the thin film transistor layer includes at least one first thin film transistor group 137, each of the first thin film transistor groups 137 includes at least two of the first thin film transistors 103, and the first gates 104 of adjacent ones of the first thin film transistors 103 within each of the first thin film transistor groups 137 are connected. The first gates 104 of the first thin film transistors 103 in adjacent groups of the first thin film transistors 137 are spaced apart in the first direction X. The connection portion 138 is provided between the first gates 104 of the first thin film transistors 103 within each of the first thin film transistor groups 137 to connect the first gates 104 of the first thin film transistors 103 within the first thin film transistor group 137.

In some embodiments, in the first direction X, one of the first via holes 112 is disposed between the first gate 104 and the second gate 105 of one of the first thin film transistors 103 in one of the first thin film transistor groups 137 to connect the first gate 104 and the second gate 105 in the first thin film transistor group 137. That is, each of the first thin film transistor groups 137 is correspondingly provided with one of the first via holes 112.

In some embodiments, in the first direction X, the first gates 104 of adjacent first thin film transistors 103 are connected through the connection portions 138. In this case, only one of the first via holes 112 is provided in one of the rows, to connect the first gate electrodes 104 and the second gate electrodes 105 of the first thin film transistors 103 in the same row, so that the resistance generated by the connection of the second gate electrode 105 and the first gate electrode 104 may be minimized, the amount of power required to maintain first gates 104 of the first thin film transistors 103 in the same row have the same potential as the second gates 105 of these first thin film transistors 103 is reduced, and the power consumption of the display panel to which the array substrate 100 is applied is reduced. At the same time, the orthographic projection of the connection portion 138 on the substrate 101 is located in the orthographic projection of the second gate electrode 105 on the substrate 101, so as to reduce shielding of light by the connection portion 138, and advantageously increase the aperture ratio of the display panel to which the array substrate 100 is applied.

In some embodiments, in the first direction X, the interval between the first gates 104 of adjacent ones of the first thin film transistor groups 137 is greater than or equal to 1 micron, the interval between the first gates 104 of adjacent ones of the first thin film transistor groups 137 is less than or equal to 6.6 microns. For example, the interval may be 1.5 microns, 2 microns, 2.5 microns, 3 microns, 3.5 microns, 4 microns, 4.5 microns, 5 microns, 5.5 microns, 6 microns, 6.5 microns, etc., in order to enhance the aperture ratio of the display panel to which the array substrate 100 is applied. The intervals between the first gates 104 of the first thin film transistor groups 137 adjacent to each other in the first direction X at pixel densities corresponding to different resolutions are different, and the interval between the first gates 104 of the first thin film transistor groups 137 adjacent to each other in the first direction X is adjusted adaptively within the above range (for example, the interval between the first gates 104 of the first thin film transistor groups 103 adjacent to each other in the first direction X, when the pixel density is greater), so that the aperture ratio of the display panel to which the array substrate 100 is applied may be effectively improved.

In some embodiments, the connection portion 138 is integrally provided with the first gates 104 of the two first thin film transistors 103 connected to the connection portion 138, thereby facilitating simplification of the processing process and saving on manufacturing costs.

Referring to FIG. 3, in some embodiments, the first via hole 112 is located between the first side 104a of the first gate 104 and the first active layer 106, and in the first direction X, the interval between the first side 104a and an orthographic projection of the first active layer 106 on the first gate 104 is greater than the interval between the second side 104b and the first active layer 106, to facilitate the placement of the first via hole 112 and the connection of the first gate 104 to the second gate 105. The interval between the first side 104a and the orthographic projection of the first active layer 106 on the first gate electrode 104 in the first direction X is a maximum interval between the first side 104a and the orthographic projection of the first active layer 106 on the first gate electrode 104 in the first direction X. The interval between the second side 104b and the orthographic projection of the first active layer 106 on the first gate electrode 104 in the first direction X is the maximum interval between the second side 104b and the orthographic projection of the first active layer 106 on the first gate electrode 104 in the first direction X.

Referring to FIG. 1, in some embodiments, the thin film transistor layer 102 includes a first gate insulation layer 113 located between the first gate 104 and the first active layer 106, and a second gate insulation layer 114 located between the second gate 105 and the first active layer 106. The first via hole 112 extends through the first gate insulation layer 113 and the second gate insulation layer 114. The first via hole 112 exposes the first gate electrode 104, and the second gate electrode 105 includes a first extension extending into the first via hole 112 and in contact with the first gate electrode 104, thereby enabling connection of the first gate electrode 104 to the second gate electrode 105.

In some embodiments, in the first direction X, the difference between the interval between the first side 104a and the orthographic projection of the first active layer 106 on the first gate 104. and the interval between the second side 104b and the orthographic projection of the first active layer 106 on the first gate 104 is greater than or equal to 1 micron and less than or equal to 2 microns, e.g., 1.2 microns, 1.5 microns, 1.8 microns, etc., to facilitate connection of the first gate 104 to the second gate 105.

In some embodiments, the interval between the second side 104b and the orthographic projection of the first active layer 106 on the first gate electrode 104 is greater than or equal to 0.5 microns, and the interval between the second side 104b and the orthographic projection of the first active layer 106 on the first gate electrode 104 is less than or equal to 2 microns, for example, may be 0.6 microns, 0.8 microns, 1 micron, 1.2 microns, 1.5 microns, 1.8 microns, etc., in order to avoid exposure of the first channel portion 109 to light from a side of the substrate 101, improving the product quality of the array substrate 100.

In the first direction X, the interval between the first side 104a and the orthographic projection of the first active layer 106 on the first gate electrode 104 is greater than or equal to 1.5 microns, and the interval between the first side 104a and the orthographic projection of the first active layer 106 on the first gate electrode 104 is less than or equal to 4 microns. For example, the interval may be 1.6 microns, 1.8 microns, 2 microns, 2.2 microns, 2.5 microns, 2.8 microns, 3 microns, 3.2 microns, 3.5 microns, 3.8 microns, etc., to facilitate connection of the first gate electrode 104 and the second gate electrode 105 while avoiding exposure of the first channel portion 109 to light from a side of the substrate 101.

In some embodiments, in the second direction Y, the first gate 104 includes a third side 104c and a fourth side 104d provided opposite to each other. The second gate 105 of the first thin film transistor 103 is located between the third side 104c and the fourth side 104d. That is, the second gate electrode 105 has a first width in the second direction Y, and the first width is smaller than the interval between the third side 104c and the fourth side 104d.

In some embodiments, in the second direction Y, the interval between the third side 104c and the orthographic projection of the second gate 105 on the first gate 104 is greater than or equal to 0.5 microns, the interval between the third side 104c and the orthographic projection of the second gate 105 on the first gate 104 is less than or equal to 2 microns. For example, the interval may be 0.6 microns, 0.8 microns, 1 micron, 1.2 microns, 1.5 microns, 1.8 microns, etc., in order to avoid exposure of the first channel portion 109 to light from a side of the substrate 101. The interval between the third side 104c and the orthographic projection of the second gate 105 on the first gate 104 in the second direction Y is the maximum interval between the third side 104c and the orthographic projection of the second gate 105 on the first gate 104.

In some embodiments, in the second direction Y, the interval between the fourth side 104d and the orthographic projection of the second gate 105 on the first gate 104 is greater than or equal to 0.5 microns, and the interval between the fourth side 104d and the orthographic projection of the second gate 105 on the first gate 104 is less than or equal to 2 microns. For example, the interval may be 0.6 microns, 0.8 microns, 1 micron, 1.2 microns, 1.5 microns, 1.8 microns, etc., in order to avoid the first channel portion 109 being exposed to light from a side of the substrate 101. The interval between the fourth side 104d and the orthographic projection of the second gate 105 on the first gate 104 in the second direction Y is the maximum interval between the fourth side 104d and the orthographic projection of the second gate 105 on the first gate 104.

In some embodiments, in the second direction Y, the first active layer 106 includes a first end and a second end provided opposite to each other, and the first gate 104 and the second gate 105 are located between the first and second ends. The first source contact 110 is located at the first end, and the first drain contact 111 is located at the second end.

In some embodiments, the thin film transistor further includes a second via hole 115 through which the first source 107 is connected to the first source contact 110 of the first active layer 106 and a third via hole 116 through which the first drain 108 is connected to the first drain contact 111 of the first active layer 106.

Referring to FIG. 1, in some embodiments, the array substrate 100 further includes a pixel electrode layer 117 on a side of the thin film transistor layer 102 away from the substrate 101. The pixel electrode layer 117 includes a pixel electrode 118. One of the first source 107 and the first drain 108 is connected to the pixel electrode 118.

In some embodiments, the first source 107 and the first drain 108 are disposed at the same or different layers. A material of the first source 107 may be same as or different from the first drain 108. When the material of the first source 107 is same as the first drain 108, the first source 107 and the first drain 108 are provided in the same layer so that the first source 107 and the first drain 108 are formed in the same process. When the material of the first source 107 is different from the first drain 108, the first source 107 and the first drain 108 are provided in a different layer so that the forming process of the first source 107 and the first drain 108 does not interfere with each other, thereby improving the product yield.

In some embodiments, the first source 107 is connected to the pixel electrode 118, and the material of the first source 107 is selected from a transparent conductive material. Alternatively, the first drain 108 is connected to the pixel electrode 118, and the material of the first drain 108 is selected from a transparent conductive material. The first drain 108 or the first source 107 connected to the pixel electrode 118 includes a transparent conductive material, it is advantageous to prevent the first source 107 or the first drain 108 from blocking light in the thickness direction of the array substrate 100, and to further improve the aperture ratio of the display panel to which the array substrate 100 is applied. The transparent conductive material may be a conductive transparent metal oxide material such as indium tin oxide.

Referring to FIG. 1, in some embodiments, the first drain 108 is connected to the pixel electrode 118, the material of the first drain 108 is selected from a transparent conductive material, the material of the first source 107 is selected from a metallic material, and the first drain 108 and the first source 107 are disposed in different layers. The first drain 108 is located on a side of the first source 107 away from the substrate 101. In this case, the thin film transistor layer 102 further includes a first interlayer insulation layer 119 located between the second gate electrode 105 and the first source 107 and a second interlayer insulation layer 120 located between the first source 107 and the first drain 108. The second via hole 115 extends through the first interlayer insulation layer 119 and the second gate insulation layer 114, and the third via hole 116 extends through the second interlayer insulation layer 120, the first interlayer insulation layer 119 and the second gate insulation layer 114. The second via hole 115 exposes the first source contact 110, and the first source 107 includes a second extension that extends into the second via hole 115 and contacts the first source contact 110, thereby enabling connection of the first source 107 to the active layer. The third via hole 116 exposes the first drain contact 111, and the first drain 108 includes a third extension extending into the third via hole 116 and in contact with the first drain contact 111, thereby enabling connection of the first drain 108 to the first active layer 106.

In some embodiments, the first drain 108 further includes a drain connection sub-portion at a side of the second interlayer insulation layer 120 away from the substrate 101, and the pixel electrode 118 is connected to the drain connection sub-portion.

Referring to FIG. 1, in some embodiments, the array substrate 100 further includes a first planarization layer 121 between the pixel electrode layer 117 and the thin film transistor layer 102. the array substrate 100 further includes a fourth via hole 122 through the first planarization layer 121, and the pixel electrode 118 and the drain connection sub-portion of the first drain 108 are connected in the fourth via hole 122.

In some embodiments, each of the fourth via holes 122 is disposed between a first drain 108 and the pixel electrode 118.

Referring to FIG. 5, in some embodiments, the fourth via hole 122 corresponding to the first drain 108 of the plurality of first thin film transistors 103 is connected in the first direction X. That is, the fourth via holes 122 corresponding to the first drains 108 of all the first thin film transistors 103 in each row are integrally provided, which facilitates simplifying the process and facilitating the subsequent arrangement of the film layers for planarization.

Referring to FIG. 1, in some embodiments, the array substrate 100 further includes a common electrode layer 123 on a side of the pixel electrode layer 117 away from the substrate 101. The common electrode layer 123 includes a common electrode 124. The array substrate 100 further includes a passivation layer 125 between the common electrode layer 123 and the pixel electrode layer 117. The passivation layer 125 is recessed at a position corresponding to the fourth via hole 122 toward the direction of the pixel electrode 118 to form a first opening in the fourth via hole 122.

In some embodiments, the array substrate 100 further includes a second planarization layer 126 filled in the first opening to obtain a planarized common electrode 124, avoiding display abnormalities of the display panel due to unevenness of the common electrode 124. A capacitor is formed between the common electrode 124 and the pixel electrode 118, and the capacitance of the capacitor may be determined by an interval and a facing area between the pixel electrode 118 and the common electrode 124. The common electrode 124 and the material of the pixel electrode 118 are all selected from transparent conductive materials, such as indium tin oxide.

Referring to FIG. 1, in some embodiments, the common electrode 124 is recessed at a position corresponding to the fourth via hole 122 toward the direction of the pixel electrode 118 to form a second opening in the fourth via hole 122. The second planarization layer 126 is filled in the second opening so as to planarize a side surface of the array substrate 100 away from the substrate 101, to avoid display abnormalities of the display panel caused by the non-planar side surface of the array substrate 100 away from the substrate 101.

Referring to FIG. 1, in some embodiments, the fourth via hole 122 is disposed facing the second gate 105. Specifically, the orthographic projection of the fourth via hole 122 on the substrate 101 is located within the orthographic projection of the second gate 105 on the substrate 101, or the orthographic projection of the second gate 105 on the substrate 101 is located within the orthographic projection of the fourth via hole 122 on the substrate 101. The second gate electrode 105 generally selects a metal material having a low resistivity. For example, the second gate electrode 105 may include a stacked layer of Al/Mo, Al/W, Mo/Al/Mo, W/Al/W. Al/Ti, Ti/Al/Ti, Mo/Cu, Mo/Ti/Cu, and the like. Therefore, the second gate electrode 105 has a low light transmittance and may occupy a part of the open area when the fourth via hole 122 is not disposed facing the second gate 105. The material difference between the film layers in the fourth via hole 122 also causes the light transmittance at the fourth via hole 122 to be low. The facing-to-facing arrangement of the second gate electrode 105 and the fourth via hole 122 advantageously reduces the influence of the aperture ratio by a portion of the array substrate 100 with the low light transmittance, and improves the aperture ratio of the display panel to which the array substrate 100 is applied.

In some embodiments, the first gate 104 is selected to be a high temperature resistant, etch resistant, low resistivity metal material. For example, the first gate 104 may include a metal or a metal stacked layer of Mo, W, W/Mo, Al/Mo, Al/W, Mo/Al/Mo, W/Al/W, Al/Ti, Ti/Al/Ti, etc.

Referring to FIG. 1, in some embodiments, the array substrate 100 further includes a non-display region FA located on at least one side of the display region AA. The thin film transistor layer 102 further includes a second thin film transistor 127 located within the non-display region FA. The second thin film transistor 127 includes a second source 128 and a second drain 129, and one of the second source 128 and the second drain 129 of the at least one second thin film transistor 127 is connected to the second gate 105 of the at least one first thin film transistor 103.

Referring to FIG. 1, in some embodiments, the second source 128 and the second drain 129 of the second thin film transistor 127 are disposed in the same layer as the second gate 105 of the first thin film transistor 103, so that one of the second source 128 and the second drain 129 of at least one of the second thin film transistors 127 is connected to the second gate 105 of at least one of the first thin film transistors 103.

In some embodiments, the array substrate 100 includes a gate drive circuit located within the non-display region FA and a pixel drive circuit located within the display region AA. The gate drive circuit may be configured to provide a gate drive signal to the pixel drive circuit. The first thin film transistor 103 may be a device constituting the pixel drive circuit, and the second thin film transistor 127 may be a device constituting the gate drive circuit.

In some embodiments, the non-display region FA includes multi-stage gate drive circuits. The gate drive circuit in each stage may correspond to the pixel drive circuits electrically connected in a corresponding one of the rows. That is, the gate drive circuits in each stage may correspond to the first thin film transistor 103 electrically connected in a corresponding one of the rows. Specifically, one of the second source 128 and the second drain 129 of at least one of the second thin film transistors 127 in one stage of the gate drive circuits may be connected to the second gates 105 of the first thin film transistors 103 in a row to transfer a gate drive signal to the first thin film transistors 103 in a row.

Referring to FIG. 1, in some embodiments, the second thin film transistor 127 further includes a third gate 130 disposed at the same level as the first gate 104. The second thin film transistor 127 further includes a second active layer 131 located between the substrate 101 and the first gate 104. The second active layer 131 includes a second channel portion 134, a second source contact portion 132 and a second drain contact portion 133 located on opposite sides of the second channel portion 134. The second source 128 is connected to the second source contact 132, and the second drain 129 is connected to the second drain contact 133. The thin film transistor layer 102 further includes a fifth via hole and a sixth via hole. The second source 128 and the second source contact 132 are connected in contact with each other in the fifth via hole, and the second drain 129 and the second drain contact 133 are connected in contact with each other in the sixth via hole. The thin film transistor layer 102 further includes a third gate insulation layer 135 disposed between the third gate 130 and the second active layer 131. The fifth via hole extends through the first gate insulation layer 113, the second gate insulation layer 114, and the third gate insulation layer 135. The sixth via hole extends through the first gate insulation layer 113, the second gate insulation layer 114, and the third gate insulation layer 135.

In some embodiments, the material of the first active layer 106 includes a metal oxide, such as indium gallium zinc oxide, or the like, such that the first thin film transistor 103 has a low leakage current, a low refresh rate, a convenience for increasing an aperture ratio, a convenience for achieving a high-brightness display, or the like.

In some embodiments, the material of the second active layer 131 includes a polysilicon (e.g., low temperature polysilicon) material such that the second thin film transistor 127 has a high mobility, a fast reaction speed, and the like.

In some embodiments, the array substrate 100 further includes a buffer layer 136 between the substrate 101 and the second active layer 131 for blocking intrusion of water, oxygen, ions, and the like from a side of the substrate 101.

In some embodiments, the substrate 101 may be a rigid substrate 101 or a flexible substrate 101, the material of the rigid substrate 101 may include at least one of glass, quartz, and the material of the flexible substrate 101 may include a polymer resin, for example, a polyimide or the like.

In the array substrate 100 according to an embodiment of the present disclosure, at least two first gates 104 in a first direction X are spaced apart, so that shielding of light by the first gates 104 is reduced, thereby increasing an aperture ratio of a display panel to which the array substrate 100 is applied.

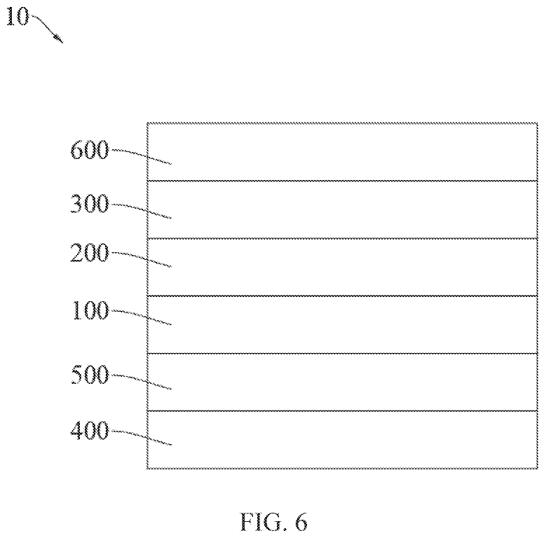

Referring to FIG. 6, an embodiment of the present disclosure further provides a display panel 10 including an array substrate 100 as described above.

For a specific structure of the array substrate 100, refer to any one of the above-described embodiments of the array substrate and the accompanying drawings, and details are not described herein.

In some embodiments, the display panel 10 further includes a liquid crystal layer 200 located at a side of the common electrode layer 123 of the array substrate 100 away from the substrate 101. The liquid crystal layer 200 includes liquid crystal. The pixel electrode 118 forms a capacitor with the common electrode 124 to provide an electric field for driving the liquid crystal to rotate.

In some embodiments, the display panel 10 further includes a color film substrate 300 on a side of the liquid crystal layer 200 away from the array substrate 100. The color film substrate 300 may include a color film layer.

In some embodiments, the display panel 10 further includes a backlight assembly 400 located on a side of the substrate 101 of the array substrate 100 away from the thin film transistor layer 102. The backlight assembly 400 is provided to provide light to the display panel for visual display.

In some embodiments, the display panel further includes a first polarizer layer 500 located between the backlight assembly 400 and the array substrate 100 and a second polarizer layer 600 located on a side of the color film substrate 300 away from the liquid crystal layer 200.

The display panel 10 may be applied to a display device such as a mobile phone, a tablet, a television, or a digital camera, or may be applied to a display device such as a VR or an AR.

An embodiment of the present disclosure discloses an array substrate and a display panel; The array substrate has a display region and includes a substrate, and a thin film transistor layer located on a side of the substrate. The thin film transistor layer includes a plurality of first thin film transistors arranged in a first direction. The first thin film transistors are located in the display region. The second gates of adjacent first thin film transistors are connected in the first direction, and the first gates of at least two first thin film transistors are arranged at intervals. The present invention reduces the light blocked by the first gates by arranging at least two first gates in the first direction at intervals, thereby increasing the aperture ratio of the display panel by using the array substrate.

It will be appreciated by those of ordinary skill in the art that equivalent substitutions or variations may be made in accordance with the technical solutions of the present disclosure and its inventive concept, and all such variations or substitutions are intended to fall within the scope of the claims appended hereto.

What is claimed is:

1. An array substrate having a display region, the array substrate comprising:
a substrate; and
a thin film transistor layer on a side of the substrate, wherein the thin film transistor layer comprises a plurality of first thin film transistors arranged in a first direction, and the first thin film transistors are located in a display region,
wherein each of the first thin film transistors comprises a first gate and a second gate, and the second gate is located on a side of the first gate away from the substrate,
the second gates of adjacent ones of the first thin film transistors are connected in the first direction, and the first gates of at least two of the first thin film transistors are spaced apart in the first direction.

2. The array substrate of claim 1, wherein the first gates of adjacent ones of the first thin film transistors are spaced apart in the first direction.

3. The array substrate of claim 2, wherein an orthographic projection of the second gate on the substrate overlaps an orthographic projection of the first gate on the substrate.

4. The array substrate of claim 2, wherein, in the first direction, an interval between the first gates of adjacent ones of the first thin film transistors is greater than or equal to 1 micron, and the interval between the first gates of adjacent ones of the first thin film transistors is less than or equal to 6.6 microns.

5. The array substrate of claim 2, wherein the thin film transistor layer further comprises a first via hole located between the first gate and the second gate, and the first gate and the second gate of each of the first thin film transistors are connected in the first via hole in the first direction.

6. The array substrate of claim 5, wherein the first thin film transistor further comprises a first active layer between the first gate and the second gate, and the first via hole is located on a side of the first active layer in the first direction.

7. The array substrate of claim 6, wherein, in the first direction, the first gate comprises a first side and a second side opposite to each other, the first active layer is located between the first side and the second side, and the first via hole is located between the first side and the first active layer; and
wherein, in the first direction, an interval between the first side and the orthographic projection of the first active layer on the first gate is greater than an interval between the second side and the first active layer.

8. The array substrate of claim 7, wherein, in the first direction, the interval between the first side and the orthographic projection of the first active layer on the first gate is greater than or equal to 1.5 μm, and the interval between the first side and the orthographic projection of the first active layer on the first gate is less than or equal to 4 μm, and
an interval between the second side and the orthographic projection of the first active layer on the first gate is greater than or equal to 0.5 μm, and the interval between the second side and the orthographic projection of the first active layer on the first gate is less than or equal to 2 μm.

9. The array substrate of claim 6, wherein the first thin film transistor further comprises a first source and a first drain located on opposite sides of the first active layer in a second direction, the second direction intersects the first direction;
the first source and the first drain are located on a side of the first active layer away from the substrate, and the first source and the first drain are respectively connected to the first active layer; and
the array substrate further includes a pixel electrode layer on a side of the thin film transistor layer away from the substrate, the pixel electrode layer comprises a pixel electrode, and one of the first source and the first drain is connected to the pixel electrode.

10. The array substrate of claim 9, wherein the first source is connected to the pixel electrode, and a material of the first source is selected from a transparent conductive material.

11. The array substrate of claim 9, wherein the first drain is connected to the pixel electrode, and a material of the first drain is selected from a transparent conductive material.

12. The array substrate of claim 2, wherein the thin film transistor layer further comprises a plurality of the first thin film transistors arranged in a second direction, the first gates of adjacent ones of the first thin film transistors are spaced apart in the second direction, and the second gates of adjacent ones of the first thin film transistors are spaced apart in the second direction; and
wherein an interval between the first gates of the first thin film transistors adjacent in the second direction is greater than an interval between the first gates of the first thin film transistors adjacent in the first direction.

13. The array substrate of claim 1, wherein a connection portion is provided between the first gates of at least two of the first thin film transistors in the first direction, and the connection portion connects the first gates of the at least two of the first thin film transistors; and
wherein an orthographic projection of the connection portion on the substrate is located within an orthographic projection of the second gate on the substrate.

14. The array substrate of claim 13, wherein the thin film transistor layer comprises at least one first thin film transistor group in the first direction, and each of the at least one first thin film transistor group comprises at least two of the first thin film transistors; and
wherein in the first direction, the first gates of adjacent ones of the first thin film transistors in each of the at least one first thin film transistor group are connected, and the first gates of the first thin film transistors in the adjacent ones of the at least one first thin film transistor group are spaced apart.

15. The array substrate of claim 14, wherein each of the at least one first thin film transistor group is provided with a first via hole.

16. The array substrate of claim 1, further comprising a non-display region located on at least one side of the display region, the thin film transistor layer further comprising second thin film transistors located within the non-display region;
wherein the second thin film transistor includes a second source and a second drain, and one of the second source and the second drain of at least one of the second thin film transistors is connected to the second gate electrode of at least one of the first thin film transistors.

17. A display panel comprising an array substrate, the array substrate comprising:
a substrate; and
a thin film transistor layer on one side of the substrate, wherein the thin film transistor layer comprises a plurality of first thin film transistors arranged in a first direction, and the first thin film transistors are located in a display region,
wherein each of the first thin film transistors comprises a first gate and a second gate, and the second gate is located on a side of the first gate away from the substrate;
the second gates of adjacent ones of the first thin film transistors are connected in the first direction, and the first gates of at least two of the first thin film transistors are spaced apart in the first direction.

18. The display panel of claim 17, wherein the first gates of adjacent ones of the first thin film transistors are spaced apart in the first direction.

19. The display panel of claim 18, wherein an orthographic projection of the second gate on the substrate overlaps an orthographic projection of the first gate on the substrate.

20. The display panel of claim 17, wherein in the first direction, a connection portion is provided between the first gates of the at least two of the first thin film transistors and the connection portion connects the first gates of the at least two of the first thin film transistors; and
wherein an orthographic projection of the connection portion on the substrate is located within an orthographic projection of the second gate on the substrate.
